(19) United States
(12) Patent Application Publication
(10) Pub. No.: US 2024/0203691 A1
(43) Pub. Date: Jun. 20, 2024

(54) APPARATUS FOR PROCESSING SUBSTRATES AND METHOD OF PROCESSING SUBSTRATES USING THE SAME

(71) Applicant: WONIK IPS CO., LTD., Pyeongtaek-si Gyeonggi-do (KR)

(72) Inventors: Yea Jin SHIN, Pyeongtaek-si Gyeonggi-do (KR); Tae In KIM, Pyeongtaek-si Gyeonggi-do (KR); Ho Jun LEE, Pyeongtaek-si Gyeonggi-do (KR); Yoon Hyung LEE, Pyeongtaek-si Gyeonggi-do (KR); Hyun Jung NAM, Pyeongtaek-si Gyeonggi-do (KR)

(73) Assignee: WONIK IPS CO., LTD., Pyeongtaek-si Gyeonggi-do (KR)

(21) Appl. No.: 18/462,269

(22) Filed: Sep. 6, 2023

(30) Foreign Application Priority Data
Dec. 19, 2022 (KR) 10-2022-0178551

(51) Int. Cl. H01J 37/32; H03H 11/28

(52) U.S. Cl. CPC H01J 37/32183; H03H 11/28; H01J 2237/327

(57) ABSTRACT

An apparatus for processing substrates may include a process chamber, a substrate supporter and an impedance matcher. The process chamber may process a plurality of the substrates using plasma. The process chamber may include a plurality of processing spaces configured to simultaneously process the substrates. The substrate supporter may be arranged in each of the processing spaces. The substrate supporter may include a plurality of stages configured to support the substrates. The impedance matcher may be provided to the process chamber. The impedance matcher may calculate impedances under the substrate supporter in regions with where the stages in simultaneously processing the substrates. The impedance matcher may compare the calculated impedances with a reference impedance to obtain an impedance compensation value. The impedance matcher may identically match the impedances in the regions with the stages with each other using the impedance compensation value. Therefore, when the substrates may be simultaneously processed using the plasma, a process deviation may be reduced to manufacture the substrates with uniformity.

### CROSS-REFERENCES TO RELATED APPLICATION

The present application claims priority under 35 U.S.C. § 119(a) to Korean application number 10-2022-0178551, filed on Dec. 19, 2022, in the Korean Intellectual Property Office, which is incorporated herein by reference in its entirety.

### BACKGROUND

### 1. Technical Field

Various embodiments generally relate to an apparatus for processing substrates and a method of processing substrates using the same, more particularly, to an apparatus for processing substrates configured to process the substrates under a uniform condition using plasma, and a method of processing substrates using the apparatus.

### 2. Related Art

Recently, an apparatus for processing a substrate may include a multi-stage configured to simultaneously process a plurality of the substrates in a process chamber so as to various needs such as improvements of productivity, process uniformity, etc.

The apparatus may include the process chamber, a plurality of showerheads and a plurality of stages. The process chamber may include a plurality of processing spaces configured to simultaneously process the substrates. The showerheads may be provided to an upper portion of the process chamber to inject a process gas into the processing spaces. The stages may be arranged in the processing spaces corresponding to the showerheads to support the substrates.

Further, the apparatus may include an RF power supply block. The RF power supply block may provide the processing spaces, for example, the showerheads with an RF power to form a plasma atmosphere in the processing spaces.

However, the apparatus with the multi-stage may have an impedance deviation by the stages or the processing spaces by complex factors such as a structural factor of the process chamber, a deviation of a hardware module, etc.

When the impedance deviation may be generated, a potential difference may be generated between the stages so that an RF power coupling may be generated. The RF power coupling may cause an imbalance between the RF powers of the stages to generate a process deviation by the stages.

### SUMMARY

Example embodiments provide an apparatus for processing substrates that may be capable of reducing a process deviation.

Example embodiments also provide a method of processing substrates using the above-mentioned apparatus.

According to example embodiments, there may be provided an apparatus for processing substrates. The apparatus may include a process chamber, a substrate supporter and an impedance matcher. The process chamber may process a plurality of the substrates using plasma. The process chamber may include a plurality of processing spaces configured to simultaneously process the substrates. The substrate supporter may be arranged in each of the processing spaces. The substrate supporter may include a plurality of stages configured to support the substrates. The impedance matcher may be provided to the process chamber. The impedance matcher may calculate impedances under the substrate supporter in regions with where the stages in simultaneously processing the substrates. The impedance matcher may compare the calculated impedances with a reference impedance to obtain an impedance compensation value. The impedance matcher may identically match the impedances in the regions with the stages with each other using the impedance compensation value.

In example embodiments, the impedance matcher may include a sensor module and a compensation value calculation module. The sensor module may measure voltages and currents in the regions with the stages in simultaneously processing the substrates in real time to calculate the impedances. The compensation value calculation module may receive the impedances from the sensor module. The compensation value calculation module may compare the impedances with the reference impedance to calculate the impedance compensation values of the regions with the stages.

In example embodiments, the impedance matcher may select any one of the stages as a master stage. The impedance matcher may set an impedance calculated from the region with the master stage as the reference impedance.

In example embodiments, the impedance matcher may select any one of the stages having a maximum RF current value, which may be measured in transmitting an RF power for generating the plasma through a ground path of the stages during the substrate may be simultaneously processed, as a master stage.

In example embodiments, the impedance matcher may include a vacuum variable capacitor module connected with the stages through transmission lines. The vacuum variable capacitor module may change a capacitor value based on the impedance compensation value to identically match the impedances of the regions with the stages with each other.

According to example embodiments, there may be provided a method of processing substrates. In the method of processing the substrates, a plurality of the substrates may be processed using plasma. An impedance of regions with a plurality of stages may be calculated in processing the substrates. The calculated impedance may be compared with a reference impedance to obtain an impedance compensation value. The impedance compensation value may be matched with the stages to match the impedances of the stages with each other.

In example embodiments, calculating the impedance compensation value may include selecting any one of the stages as a master stage, and calculating the impedance compensation value of the regions with the rest stages based on the impedance calculated from the region with the master stage.

In example embodiments, the master stage may have a maximum RF current value, which may be measured in transmitting an RF power for generating the plasma through a ground path of the stages during the substrate may be simultaneously processed.

In example embodiments, calculating the impedance compensation value may include calculating a reference impedance from a region with a master stage among the stages, and comparing the reference impedance with the impedances of the regions with the rest stages to obtain the impedance compensation value of the regions with the stages.

According to example embodiments, the apparatus may collect the impedances under the stages in simultaneously processing the substrates using the plasma. The apparatus may match the collected impedances with each other to transmit a same power to the stages. Thus, a deviation between the process chambers may be controlled to uniformly process the substrates.

### BRIEF DESCRIPTION OF THE DRAWINGS

The above and another aspects, features and advantages of the subject matter of the present disclosure will be more clearly understood from the following detailed description taken in conjunction with the accompanying drawings, in which:

FIG. 1 is a view illustrating an apparatus for processing substrates in accordance with example embodiments; and

FIG. 2 is a flow chart illustrating a method of processing substrates in accordance with example embodiments.

### DETAILED DESCRIPTION

Various embodiments of the present invention will be described in greater detail with reference to the accompanying drawings. The drawings are schematic illustrations of various embodiments (and intermediate structures). As such, variations from the configurations and shapes of the illustrations as a result, for example, of manufacturing techniques and/or tolerances, are to be expected. Thus, the described embodiments should not be construed as being limited to the particular configurations and shapes illustrated herein but may include deviations in configurations and shapes which do not depart from the spirit and scope of the present invention as defined in the appended claims.

The present invention is described herein with reference to cross-section and/or plan illustrations of idealized embodiments of the present invention. However, embodiments of the present invention should not be construed as limiting the inventive concept. Although a few embodiments of the present invention will be shown and described, it will be appreciated by those of ordinary skill in the art that changes may be made in these embodiments without departing from the principles and spirit of the present invention.

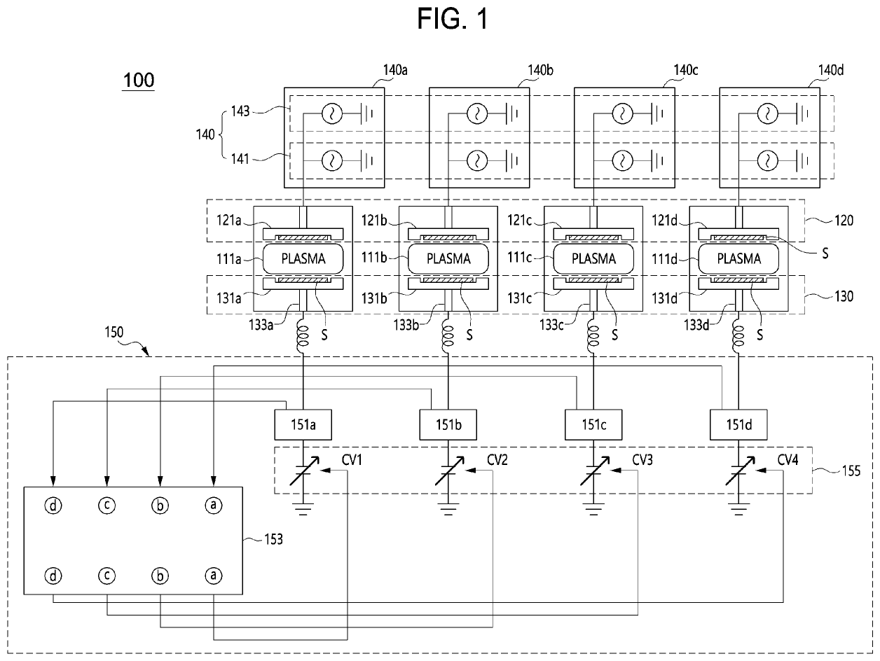

FIG. 1 is a view illustrating an apparatus for processing substrates in accordance with example embodiments.

Referring to FIG. 1, an apparatus 100 of processing substrates in accordance with example embodiments may include a process chamber 110, a gas injector 120, a substrate supporter 130, a radio frequency (RF) power supply block 140 and an impedance matcher 150.

The process chamber 110 may include a plurality of processing spaces 111a, 111b, 111c and 111d. A plasma atmosphere may be formed in each of the processing spaces 111a, 111b, 111c and 111d to simultaneously process the substrates.

The process chamber 110 may have an airtight structure. The process chamber 110 may be connected with an exhaust port or a vacuum pump to exhaust a process gas from the processing spaces 111a, 111b, 111c and 111d and to control a vacuum degree in the processing spaces 111a, 111b, 111c and 111d. The process chamber 110 may include a plurality of sidewalls configured to define the processing spaces 111a, 111b, 111c and 111d and a cover arranged on upper ends of the sidewalls.

In example embodiments, the process chamber 110 may include the fourth processing spaces 111a, 111b, 111c and 111d, but not limited thereto. The process chamber 110 may include at least two processing spaces.

Further, the process chamber 110 may be electrically grounded.

The gas injector 120 may inject the process gas supplied from a gas tank outside the process chamber 110 into the processing spaces 111a, 111b, 111c and 111d. The gas injector 120 may be arranged at an upper portion of the process chamber 110.

The gas injector 120 may include a plurality of showerheads 121a, 121b, 121c and 121d provided to the processing spaces 111a, 111b, 111c and 111d, respectively. The showerheads 121a, 121b, 121c and 121d may face a plurality of stages 131a, 131b, 131c and 131d to inject the process gas to the substrates S on the stages 131a, 131b, 131c and 131d.

The gas injector 120 may include an inlet hole through which the process gas may be introduced into the process chamber 110. The inlet hole may be formed at an upper surface or a side surface of the process chamber 110. Each of the showerheads 121a, 121b, 121c and 121d may include a plurality of injection holes facing the substrates S. Although not depicted in drawings, the gas injector 120 may be connected with a gas supplier. A controller may be arranged between the gas injector 120 and the gas supplier to control a flux of the process gas.

The substrate supporter 130 may include the stages 131a, 131b, 131c and 131d on which the substrates S may be placed. The stages 131a, 131b, 131c and 131d may have a shape corresponding to a shape of the substrate S, but not limited thereto. The stages 131a, 131b, 131c and 131d may have various shapes configured to stable support the substrates S. For example, the stages 131a, 131b, 131c and 131d may have a size lager than a size of the substrates S.

The substrate supporter 130 may include a plurality of supports 133a, 133b, 133c and 133d and a driving motor. The supports 133a, 133b, 133c and 133d may lift the stages 131a, 131b, 131c and 131d. The driving motor may be connected to the supports 133a, 133b, 133c and 133d to provide the supports 133a, 133b, 133c and 133d with a driving force. A bellows may be connected to the supports 133a, 133b, 133c and 133d to seal the supports 133a, 133b, 133c and 133d. The substrate supporter 130, i.e., the stages 131a, 131b, 131c and 131d may be electrically connected to a ground terminal.

The RF power supply block 140 may apply an RF power to the process chamber 110 to form the plasma atmosphere. For example, the RF power supply block 140 may apply the RF power to the gas injector 120. In this case, the gas injector 120 may correspond to a power supply electrode or an upper electrode. The RF power supply block 140 may include at least one an RF power source. In example embodiments, in order to provide the processing spaces 111a, 111b, 111c and 111d with the RF power, respectively, the RF power supply block 140 may include a plurality of the RF power suppliers 140a, 140b, 140c and 140d corresponding to the processing spaces 111a, 111b, 111c and 111d, but not limited thereto. For example, a single RF power supplier may apply the RF power to the processing spaces 111a, 111b, 111c and 111d.

Particularly, each of the RF power suppliers 140a, 140b, 140c and 140d may include a first RF power source 141 having a first frequency band and a second RF power source 143 having a second frequency band higher than the first frequency band to form independent plasma environments by process conditions in the processing spaces 111a, 111b, 111c and 111d. A dual frequency power source including the first RF power source 141 and the second RF power source 143 may have the different frequency bands in accordance with the process conditions or process steps to accurately control a process.

More particularly, the first RF power source 141 may include a low frequency (LF) power source having the first frequency band of at least 370 kHz. The second RF power source 143 may include a high frequency (HF) power source having the second frequency band of at least 27.12 MHz. The first frequency band of the HF power source may be about 5 MHz to about 60 MHZ, for example, about 13.56 MHz to about 27.12 MHz. The second frequency band of the LF power source may be about 100 kHz to about 5 MHz, for example, about 300 kHz to about 600 kHz. In example embodiments, the second frequency band may be about 13.56 MHz to about 27.12 MHz. The first frequency band may be about 300 kHz to about 600 kHz.

In example embodiments, each of the RF power supplier 140a, 140b, 140c and 140d may apply the RF power to the showerheads 121, 121b, 121c and 121d, respectively.

The impedance matcher 150 may be provided to the process chamber 110 to calculate impedances of the stages 131a, 131b, 131c and 131d during the substrates S may be simultaneously processed.

For example, the impedance matcher 150 may be connected to lower surfaces of the stages 131a, 131b, 131c and 131d to collect the impedances of the stages 131a, 131b, 131c and 131d.

The impedance matcher 150 may include a sensor module 151a, 151b, 151c and 151d, a compensation module calculation module 153 and a capacitor module 155.

The sensor module 151a, 151b, 151c and 151d may be connected to the lower surfaces of the stages 131a, 131b, 131c and 131d. The sensor module 151a, 151b, 151c and 151d may measure voltages and current under the stages 131a, 131b, 131c and 131d. The sensor module 151a, 151b, 151c and 151d may detect the impedances. For example, the sensor module 151a, 151b, 151c and 151d may include a voltage-current sensor (for example, I-V sensor). The detected voltages and currents may be provided to the compensation value calculation module 153. The compensation value calculation module 153 may calculate the impedances. The sensor module 151a, 151b, 151c and 151d may transmit the impedances of regions with the stages 131a, 131b, 131c and 131d to the compensation value calculation module 153.

The compensation value calculation module 153 may receive the impedances or the voltages/currents of the stages 131a, 131b, 131c and 131d from the sensor module 151a, 151b, 151c and 151d. The compensation value calculation module 153 may compare the impedances with a reference impedance to obtain impedance compensation values.

The compensation value calculation module 153 ma transmit the impedance compensation values of the stages 131a, 131b, 131c and 131d to the capacitor module 155. The compensation value calculation module 153 may include an algorithm receiving the impedances under the stages 131a, 131b, 131c and 131d to automatically calculate the impedance compensation values.

The compensation value calculation module 153 may select any one of the stages 131a, 131b, 131c and 131d as a master stage M. The compensation value calculation module 153 may set an impedance of the master stage M as the reference impedance. The compensation value calculation module 153 may set remaining stages except for the master stage M as slave stages S1, S2 and S3. The compensation value calculation module 153 may compare the impedance of the master stage M with the impedances of the slave stages S1, S2 and S3 to calculate the impedance compensation values of the slave stages S1, S2 and S3.

For example, the compensation value calculation module 153 may select a stage having a maximum current value through the sensor module 151a, 151b, 151c and 151d as the master stage M

When the RF power may be supplied to form the plasma, a voltage difference may be generated between the showerheads 121a, 121b, 121c and 121d and the stages 131a, 131b, 131c and 131d. A current by the voltage difference may flow to ground terminals connected to the stages 131a, 131b, 131c and 131d. The sensor module 151a, 151b, 151c and 151d may be connected to the lower surfaces of the stages 131a, 131b, 131c and 131d adjacent to the ground terminals to detect the currents by the stages 131a, 131b, 131c and 131d and the voltage difference between the processing spaces 111a, 111b, 111c and 111d, thereby obtaining the impedances.

Although the same RF power may be applied to the showerheads 121a, 121b, 121c and 121d of the processing spaces 111a, 111b, 111c and 111d, the currents flowing to the spaces under the stages 131a, 131b, 131c and 131d of the processing spaces 111a, 111b, 111c and 111d may be different from each other by various reasons of the process chamber 110. A difference between the currents may cause a difference between qualities generated from the processing spaces 111a, 111b, 111c and 111d. Thus, the impedance matcher 150 may measure the impedance difference from the difference between the currents by the processing spaces 111a, 111b, 111c and 111d to perform a compensation operation for reducing the impedance difference.

The compensation value calculation module 153 may set the stage having the maximum current value as the master stage M based on the current values of the stages 131a, 131b, 131c and 131d. Alternatively, the compensation value calculation module 153 may set an average impedance of the impedances the stages 131a, 131b, 131c and 131d as the reference impedance.

Particularly, the compensation value calculation module 153 may set a stage having an impedance nearest to the average impedance of the impedances as the master stage M. The compensation value calculation module 153 may set the remaining stages as the slave stages S. The compensation value calculation module 153 may compensate the impedances of the slave stage S based on the reference impedance of the master stage M. Alternatively, the compensation value calculation module 153 may set a stage having a minimum impedance value as the master stage M.

Further, the compensation value calculation module 153 may set a stage having a maximum value as the master stage M.

The compensation value calculation module 153 may calculate the impedance compensation values of the slave stages S1, S2 and S3 using the reference impedance of the master stage M among the stages 131a, 131b, 131c and 131d.

The capacitor module 155 may receive the impedance compensation value to match the impedances of the stages 131a, 131b, 131c and 131d with each other.

The capacitor module 155 may include variable capacitors Cv1, Cv2, Cv3 and Cv4 connected to the stages 131a, 131b, 131c and 131d. The variable capacitors Cv1, Cv2, Cv3 and Cv3 may receive the impedance compensation values. Capacitances of the variable capacitors Cv1, Cv2, Cv3 and Cv4 may be adjusted to match the impedances with each other. For example, the variable capacitors Cv1, Cv2, Cv3 and Cv4 may include at least one of a vacuum variable capacitor, an electrical variable capacitor and a hybrid variable capacitor having a capacitance changed by a mechanical and electrical way. Each of the variable capacitors Cv1, Cv2, Cv3 and Cv4 may include a plurality of capacitor arrays.

For example, the variable capacitors Cv1, Cv2, Cv3 and Cv4 may receive the impedance compensation values by the stages provided from the compensation value calculation module 153. The capacitances of the variable capacitors Cv2, Cv2, Cv3 and Cv4 may be individually changed based on the impedance compensation values to provide the stages 131a, 131b, 131c and 131d with the same impedance. Thus, the same impedance may be provided to the processing spaces 111a, 111b, 111c and 111d.

According to example embodiments, the apparatus 100 may monitor the impedances under the stages 131a, 131b, 131c and 131d in real time. The apparatus 100 may calculate the capacitance under the stages 131a, 131b, 131c and 131d to obtain the impedance compensation values. The apparatus 100 may set the impedance compensation values to automatically control the impedances in real time.

Any one of the stages 131a, 131b, 131c and 131d may be the master stage M. The remaining stages may be the slave stages S1, S2 and S3. The impedance matcher 150 may control the impedances of the slave stages S1, S2 and S3 based on the impedance compensation values obtained from the reference impedance of the master stage M.

In example embodiments, the elements of the impedance matcher 150 may be connected with a wire connection or a wireless connection to transmit signals and information.

Therefore, the apparatus 100 may collect the impedances under the stages in simultaneously processing the substrates. The apparatus may match the impedances with each other to provide the stages with the same power based on the collected impedances. Thus, the deviation of the process chamber may be readily controlled to obtain a uniform result of the processed substrates.

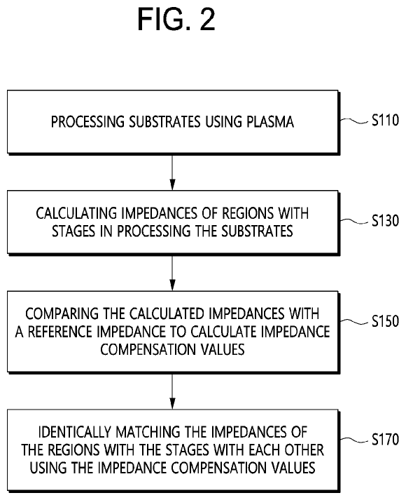

FIG. 2 is a flow chart illustrating a method of processing substrates in accordance with example embodiments.

Referring to FIG. 2, a method of processing substrates may include step S110 for processing the substrates, step S130 for calculating impedances, step S150 for calculating impedance compensation values and step S170 for matching the impedances. The method may be performed using the apparatus 100.

In step S110, the substrates may be processed using plasma. The processing may include forming a layer, etching a layer using the plasma, etc. The process may include a cleaning process using the plasma.

In step S130, the impedances of regions where the stages 131a, 131b, 131c and 131d may be arranged may be calculated in processing the substrates. Particularly, the sensor module 151a, 151b, 151c and 151d may collect the impedances under the stages 131a, 131b, 131c and 131d. The impedances collected by the sensor module 151a, 151b, 151c and 151d may be transmitted to the compensation value calculation module 153 through the communication.

In step S150, the impedances may be compared with the reference impedance to calculate the impedance compensation values.

In example embodiments, the compensation value calculation module 153 may compare the impedances received from the sensor module 151a, 151b, 151c and 151d with the reference impedance to calculate the impedance compensation values.

Particularly, the compensation value calculation module 153 may select any one of the stages 131a, 131b, 131c and 131d as the master stage M. The compensation value calculation module 153 may calculate the impedance compensation values of the regions with the rest stages, i.e., the slave stages S1, S2 and S3 based on the impedance of the master stage M. The compensation value calculation module 153 may transmit the impedance compensation values to the impedance matcher 150. The master stage M may be selected by the above-mentioned manners.

In step S170, the impedance compensation values may be matched with the rest stages to match the impedances with each other, thereby provide the stages 131a, 131b, 131c and 131d with the same power.

In example embodiments, the capacitor module 155 may receive the impedance compensation values from the compensation value calculation module 153. The capacitor module 155 may match the impedance compensation values with the stages 131a, 131b, 131c and 131d to match the impedances of the stages 131a, 131b, 131c and 131d, thereby providing the stages 131a, 131b, 131c and 131d with the same value.

According to example embodiments, the apparatus 100 may collect the impedances under the regions with the stages 131a, 131b, 131c and 131d. The collected impedances may include the impedance deviation and the plasma deviation. That is, the apparatus 100 may detect the final impedance including the impedance deviation and the plasma deviation. The apparatus 100 may automatically calculate the impedance compensation values to match the impedances with the stages 131a, 131b, 131c and 131d so that the same power may be provided to the stages 131a, 131b, 131c and 131d to reduce the process deviation. Particularly, the substrates processed by the apparatus 100 may have uniform properties. For example, although the substrates may have different stresses, the substrates processed by the apparatus 100 may have a same stress to have the low process deviation. Therefore, the apparatus and the method of example embodiments may control variables of the process as well as the impedance compensation. As a result, the apparatus and the method may also be used for improving the properties of the substrates manufactured by a same process.

In example embodiments, the apparatus may not optimize a current flowing through the substrates by matching the impedance. When the substrates may be processed in the processing spaces, the apparatus may match the processing conditions of the processing spaced with each other to form the different process deviations.

The above described embodiments of the present invention are intended to illustrate and not to limit the present invention. Various alternatives and equivalents are possible. The invention is not limited by the embodiments described herein. Nor is the invention limited to any specific type of semiconductor device. Another additions, subtractions, or modifications are obvious in view of the present disclosure and are intended to fall within the scope of the appended claims.

What is claimed is:

1. An apparatus for processing substrates, the apparatus comprising:
a process chamber including a plurality of processing spaces in which the substrates are simultaneously processed using plasma;
a substrate supporter provided to each of the processing spaces, the substrate supporter including a plurality of stages configured to support the substrates; and
an impedance matcher provided to the process chamber, the impedance matcher detecting impedances under the stages in simultaneously processing the substrate, comparing the detected impedances with a reference impedance to calculate impedance compensation values by the stages, and identically matching the impedances of the stages based on the impedance compensation values.

2. The apparatus of claim 1, wherein the impedance matcher comprises:
a sensor module measuring voltages and current of regions with the stages in real time during the substrates are simultaneously process to detect the impedances; and
a compensation value calculation module calculating the impedance compensation values based on the impedances by the stages from the sensor module.

3. The apparatus of claim 2, wherein the sensor module is connected to lower surfaces of the stages to detect the voltages and the currents flowing through the lower surfaces of the stages.

4. The apparatus of claim 1, wherein the impedance matcher selects any one of the stages as a master stage and the impedance matcher sets an impedance of the master stage as the reference impedance.

5. The apparatus of claim 4, wherein the master stage has a maximum current value among current values of the stages.

6. The apparatus of claim 1, wherein the reference impedance is an impedance of a stage selected from the stages.

7. The apparatus of claim 1, wherein the impedance matcher comprises a capacitor module including a plurality of variable capacitors connected to the stages and the variable capacitors have capacitance changed in accordance with the impedance compensation values.

8. A method of processing substrates processed in a plurality of processing spaces having a plasma atmosphere where a plurality of stages are provided, the method comprising:
detecting impedances of the stages;
comparing the impedances with a reference impedance to calculate impedance compensation values by the stages; and
identically matching the impedances with each other based on the impedance compensation values.

9. The method of claim 8, wherein calculating the impedance compensation values comprises:
selecting any one of the stages as a master stage; and
calculating the impedance compensation values of regions with the rest stages based on an impedance of a region with the master stage.

10. The method of claim 9, wherein the master stage has a maximum current value among current values of the stages.

11. The method of claim 8, wherein calculating the impedance compensation values comprises:
calculating the reference impedance of a region with a master stage selected from the stages; and
comparing the reference impedance with the impedances of regions with the rest stages to calculate the impedance compensation values of the regions with the stages.
